(19) United States
(12) Patent Application Publication
(10) Pub. No.: US 2023/0138592 A1
(43) Pub. Date: May 4, 2023

(54) METHOD FOR MANUFACTURING LIGHT-EMITTING ELEMENT

(71) Applicants: NICHIA CORPORATION, Anan-shi (JP); HAMAMATSU PHOTONICS K.K., Hamamatsu-shi (JP)

(72) Inventors: Naoto INOUE, Anan-shi (JP); Minoru YAMAMOTO, Anan-shi (JP); Taichi OKUBO, Kurashiki-shi (JP); Hiroaki TAMEMOTO, Anan-shi (JP); Ryota SUGIO, Hamamatsu-shi (JP); Yusuke SEKIMOTO, Hamamatsu-shi (JP)

(73) Assignees: NICHIA CORPORATION, Anan-shi (JP); HAMAMATSU PHOTONICS K.K., Hamamatsu-shi (JP)

(21) Appl. No.: 17/964,034

(22) Filed: Oct. 12, 2022

(30) Foreign Application Priority Data
Oct. 29, 2021 (JP) 2021-177922

(51) Int. Cl. H01L 33/00

(52) U.S. Cl. CPC H01L 33/0095

(57) ABSTRACT

A method for manufacturing a light-emitting element includes preparing a wafer; a laser beam irradiation process; and a separation process. The laser beam irradiation process includes a first irradiation process of forming a plurality of first modified portions, and a second irradiation process of forming a plurality of second modified portions. The second modified portions are formed in the second irradiation process so that a length in a thickness direction of the sapphire substrate of the second modified portions is greater than a length in the thickness direction of the first modified portions.

### CROSS-REFERENCE TO RELATED APPLICATION

This application claims priority to Japanese Patent Application No. 2021-177922, filed on Oct. 29, 2021, the disclosure of which is hereby incorporated by reference in its entirety.

### BACKGROUND

The present invention relates to a method for manufacturing a light-emitting element.

Generally, for example, a light-emitting element is obtained by dicing a wafer in which a semiconductor layer is formed on a sapphire substrate. Methods for dicing a wafer include, for example, a known method in which a laser beam is concentrated in the substrate interior to form modified portions, and the wafer is cleaved using the modified portions as starting points as described in JP-A 2018-52814 (Kokai).

### SUMMARY

A method for manufacturing a light-emitting element is provided in which unintended cracking after laser beam irradiation can be reduced while reducing degradation of the electrical characteristics of a semiconductor layer due to the laser beam.

According to one embodiment, a method for manufacturing a light-emitting element includes preparing a wafer, the wafer including a sapphire substrate including a first surface on a first surface side and a second surface on a second surface side opposite to the first surface side, and a semiconductor layer located at the first surface; a laser beam irradiation process of irradiating a laser beam into the sapphire substrate from the second surface side; and a separation process of separating the wafer into a plurality of light-emitting elements after the laser beam irradiation process. The laser beam irradiation process includes a first irradiation process of forming a plurality of first modified portions along a first direction parallel to the second surface by irradiating the laser beam along the first direction, the plurality of first modified portions being formed at positions that are a first distance from the second surface in a thickness direction of the sapphire substrate, and a second irradiation process of forming a plurality of second modified portions along the first direction by irradiating the laser beam along the first direction, the plurality of second modified portions being formed at positions that are a second distance from the second surface in the thickness direction, the second distance being less than the first distance, the plurality of second modified portions being arranged in the thickness direction with the plurality of first modified portions. The second modified portions are formed in the second irradiation process so that a length in the thickness direction of the second modified portions is greater than a length in the thickness direction of the first modified portions.

According to such a method for manufacturing a light-emitting element, unintended cracking after laser beam irradiation can be reduced while reducing degradation of the electrical characteristics of a semiconductor layer due to the laser beam.

### BRIEF DESCRIPTION OF THE DRAWINGS

FIG. 1 is a plan view of a wafer of embodiments;

FIG. 2 is a cross-sectional view of the wafer of the embodiments;

FIG. 3 is a cross-sectional view explaining a first irradiation process of a first embodiment;

FIG. 4 is a cross-sectional view explaining a second irradiation process of the first embodiment;

FIG. 5 is a cross-sectional view explaining a third irradiation process and a fourth irradiation process of the first embodiment;

FIG. 6 is a cross-sectional view explaining a laser beam irradiation process of a second embodiment;

FIG. 7A and FIG. 7B are plan views explaining a separation process in a method for manufacturing a light-emitting element of the embodiments;

FIG. 8A is a view explaining a light concentration state without aberration correction;

FIG. 8B is a view explaining a weakly-corrected light concentration state in which an aberration correction amount is less than an ideal aberration correction amount;

FIG. 8C is a view explaining an ideal light concentration state;

FIG. 9 is a cross-sectional view showing an example of a shape of a concentration region inside a sapphire substrate of a laser beam for forming modified portions according to the embodiments; and

FIG. 10 is a cross-sectional view of a light-emitting element manufactured by the first embodiment.

### DETAILED DESCRIPTION

Exemplary embodiments will now be described with reference to the drawings. Similar components in the drawings are marked with like reference numerals. Because the drawings schematically show embodiments, the scales, spacing, positional relationships, and the like of the members may be exaggerated, or some of the members may not be illustrated. Also, end views that show only cross sections may be used as cross-sectional views.

A method for manufacturing a light-emitting element according to an embodiment includes a process of preparing a wafer, a laser beam irradiation process, and a separation process of separating the wafer into multiple light-emitting elements.

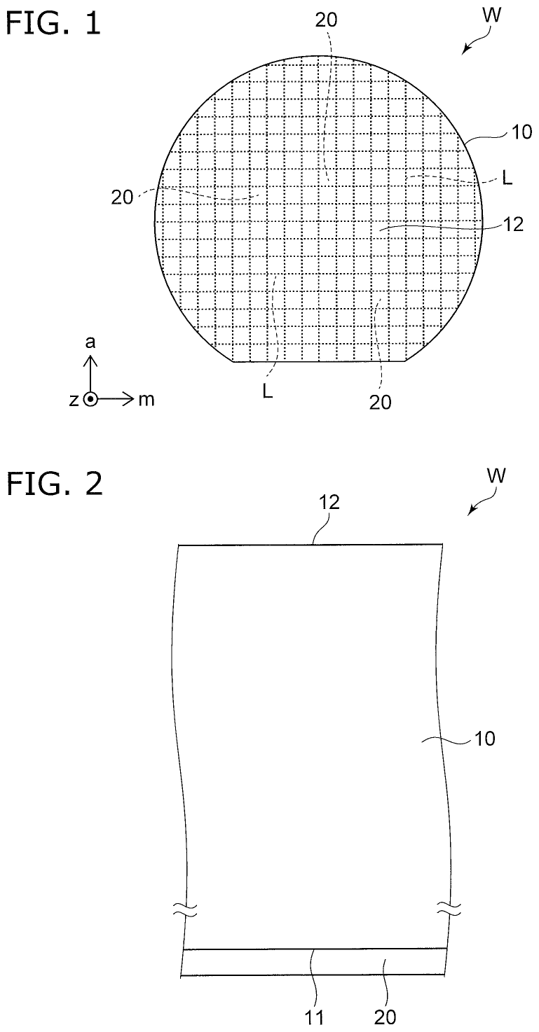

FIG. 1 is a plan view of a wafer W. FIG. 2 is a partial cross-sectional view showing a cross section of the wafer W.

The wafer W includes a sapphire substrate 10 and a semiconductor layer 20. The sapphire substrate 10 includes a first surface 11, and a second surface 12 positioned at a side opposite to the first surface 11. The semiconductor layer 20 is located at the first surface 11 of the sapphire substrate 10. Also, electrodes that are electrically connected with the semiconductor layer 20 and a protective film that covers the semiconductor layer 20 can be formed at the first surface 11 side of the sapphire substrate 10.

The first surface 11 is, for example, a c-plane of the sapphire substrate 10. The first surface 11 can be oblique to the c-plane of the sapphire substrate 10 in a range in which the semiconductor layer 20 can be formed with good crystallinity. In FIG. 1, a first direction a is parallel to the second surface 12 and is along an a-axis direction of the sapphire substrate 10. A second direction m is orthogonal to the first direction a and is along an m-axis direction of the sapphire substrate 10. A thickness direction z of the sapphire substrate 10 is orthogonal to the first and second directions a and m. The thickness of the sapphire substrate is, for example, not less than 30 μm and not more than 1500 μm.

The semiconductor layer 20 includes, for example, a nitride semiconductor represented by InₓAl_{y}Ga_{1-x-y}N (0≤x≤1, 0≤y≤1, and x+y≤1). The semiconductor layer 20 includes an active layer that emits light. The peak wavelength of the light emitted by the active layer is, for example, not less than 280 nm and not more than 650 nm. The peak wavelength of the light emitted by the active layer can be less than 280 nm or greater than 650 nm.

In the laser beam irradiation process, a laser beam is irradiated into the wafer W along multiple planned singulation lines L. For example, the planned singulation lines L have a lattice shape. The planned singulation lines L are virtual lines defined in the wafer W.

For example, the semiconductor layer 20 is not located at the planned singulation lines L. Or, the semiconductor layer 20 can be formed over the entire surface of the first surface 11 of the sapphire substrate 10.

The laser beam irradiation process is performed after preparing the wafer W described above.

The laser beam is scanned along each of the multiple planned singulation lines L while being irradiated into the sapphire substrate 10 from the second surface 12 side. For example, the laser beam is emitted in pulses. The pulse width of the laser beam is, for example, not less than 100 fsec and not more than 1000 psec. For example, a Nd:YAG laser, a Yb:YAG laser, a Yb:KGW laser, a titanium sapphire laser, a Nd:YVO₄ laser, a Nd:YLF laser, or the like is used as the laser light source. The wavelength of the laser beam is a wavelength of light that passes through the sapphire substrate 10. For example, the laser beam has a peak wavelength in a range of not less than 500 nm and not more than 1200 nm.

### First Embodiment

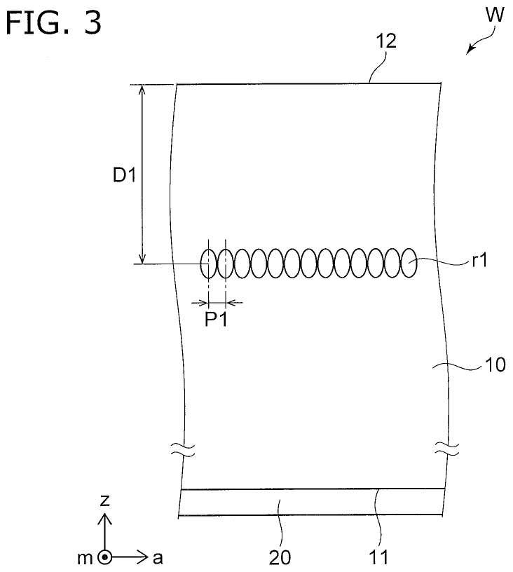

A laser beam irradiation process according to a first embodiment will now be described with reference to FIGS. 3 to 5. The laser beam irradiation process according to the first embodiment includes a first irradiation process and a second irradiation process.

### First Irradiation Process

In the first irradiation process, a laser beam is irradiated along the first direction a. Thereby, as shown in FIG. 3, multiple first modified portions r1 are formed along the first direction a at a position that is a first distance D1 from the second surface 12 in the thickness direction z of the sapphire substrate 10. The first distance D1 is the distance from the second surface 12 to the center of the first modified portion r1 when viewed in cross-section.

The laser beam is concentrated at a position inside the sapphire substrate 10 that is the first distance D1 from the second surface 12; and the energy of the laser beam is concentrated at this position. A modified portion (in the example, the first modified portion r1) is formed in the concentration region of the laser beam inside the sapphire substrate 10. The modified portion is a region in which the density, refractive index, mechanical strength, and other physical characteristics are different from those of the surrounding unmodified regions. Also, for example, the modified portion is a portion of the sapphire substrate 10 that is less light-transmissive than portions not irradiated with the laser beam.

For example, the multiple first modified portions r1 are formed to be separated from each other along the first direction a. Or, the multiple first modified portions r1 can be formed in a continuous line shape extending in the first direction a by causing portions of the first modified portions r1 next to each other in the first direction a to contact or overlap.

Cracks are generated from the multiple first modified portions r1 formed inside the sapphire substrate 10. Cracks that extend from the first modified portion r1 toward at least the second surface 12 are formed inside the sapphire substrate 10.

### Second Irradiation Process

The second irradiation process is performed after the multiple first modified portions r1 are formed by the first irradiation process.

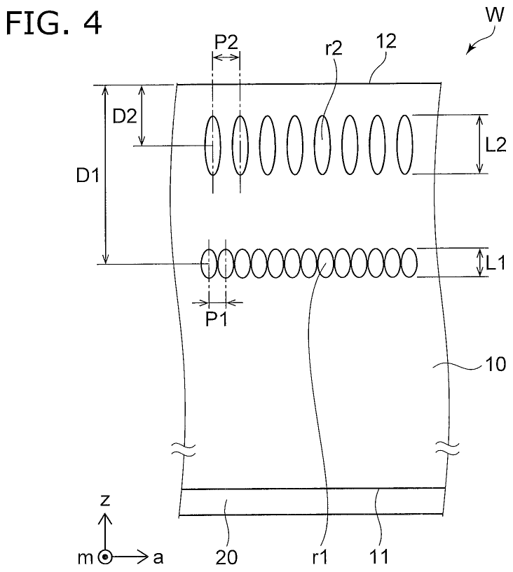

In the second irradiation process as shown in FIG. 4, multiple second modified portions r2 are formed along the first direction a by irradiating the laser beam along the first direction a at a position that is a second distance D2, which is less than the first distance D1, from the second surface 12 in the thickness direction z. The second distance D2 is the distance from the second surface 12 to the center of the second modified portion r2 when viewed in cross-section. The multiple second modified portions r2 are formed along the first direction a to be arranged in the thickness direction z with the multiple first modified portions r1. The multiple second modified portions r2 and the multiple first modified portions r1 are formed to overlap when viewed in top-view.

For example, the multiple second modified portions r2 are formed to be separated from each other along the first direction a. Or, the multiple second modified portions r2 can be formed in a continuous line shape extending in the first direction a by causing portions of the second modified portions r2 next to each other in the first direction a to contact or overlap.

Similarly to the first modified portion r1, cracks that extend from the second modified portion r2 toward at least the second surface 12 are formed inside the sapphire substrate 10. It is favorable for the cracks from the second modified portions r2 to reach the second surface 12. Also, it is favorable for the cracks from the second modified portions r2 to reach the first modified portions r1.

The second modified portion r2 is formed in the second irradiation process so that a length L2 in the thickness direction z of the second modified portion r2 is greater than a length L1 in the thickness direction z of the first modified portion r1.

The concentration region of the laser beam is the region having a laser beam intensity per unit volume that is enough to form the modified portion. There is a tendency for the size of the modified portion in the thickness direction z to increase as the length in the thickness direction z of the concentration region of the laser beam increases.

When the laser beam is concentrated inside the sapphire substrate 10 from the second surface 12 side of the sapphire substrate 10, the semiconductor layer 20 that is formed at the first surface 11 of the sapphire substrate 10 is easily affected by escaped light from the concentration region of the laser beam; and electrical characteristics of the semiconductor layer 20 are easily degraded. As the size of the concentration region in the thickness direction z inside the sapphire substrate 10 is increased, the escaped light from the concentration region is increased, and the electrical characteristics of the semiconductor layer 20 are more easily degraded. The escaped light from the concentration region is light of the laser beam that escapes to the semiconductor layer 20 side without contributing to the formation of the modified portion. As the size of the concentration region in the thickness direction z is increased, the light concentration of the laser beam degrades, causing more light to escape to the semiconductor layer 20 side without contributing to the formation of the modified portion.

According to the embodiment, the first modified portion r1 is formed so that the length L1 in the thickness direction z of the first modified portion r1 formed by concentrating the laser beam at a position more proximate to the semiconductor layer 20 than the second modified portion r2 is less than the length L2 in the thickness direction z of the second modified portion r2. In other words, the length in the thickness direction z of a first concentration region of the laser beam in the first irradiation process is set to be less than the length in the thickness direction z of a second concentration region of the laser beam in the second irradiation process. The escaped light from the first concentration region that is more proximate to the semiconductor layer 20 than the second concentration region can be reduced thereby, and the degradation of the electrical characteristics of the semiconductor layer 20 due to the laser beam can be reduced.

There is a tendency for the fracture strength of the sapphire substrate 10 after the laser beam is irradiated to be dependent on the size of the modified portion; for example, the fracture strength can be increased by increasing the size of the modified portion. By increasing the fracture strength of the sapphire substrate 10, unintended cracking of the sapphire substrate 10 before the separation process can be reduced. For example, unintended cracking of the sapphire substrate 10 may cause chipping of the protective film covering the semiconductor layer 20 in the separation process and may cause appearance defects. For example, the fracture strength can be expressed as the force (newtons (N)) necessary when cleaving the wafer W by pressing a pressing member on the planned singulation lines L.

According to the embodiment, the second modified portion r2 is formed so that the length L2 in the thickness direction z of the second modified portion r2 in the second irradiation process forming the second modified portion r2 at a position that is more distant to the semiconductor layer 20 than the first modified portion r1 is greater than the length L1 in the thickness direction z of the first modified portion r1. That is, the second irradiation process is performed so that the size of the second modified portion r2 is greater than the size of the first modified portion r1. The fracture strength of the sapphire substrate 10 can be increased thereby, and unintended cracking of the sapphire substrate 10 can be reduced. As a result, for example, chipping of the protective film covering the semiconductor layer 20 can be reduced.

The length in the thickness direction z of the second concentration region forming the second modified portion r2 is greater than the length in the thickness direction z of the first concentration region forming the first modified portion r1; and the escaped light from the second concentration region is more than the escaped light from the first concentration region. However, because the second concentration region is more distant to the semiconductor layer 20 than the first concentration region, the escaped light from the second concentration region does not easily affect the semiconductor layer 20. Accordingly, by performing the second irradiation process so that the size of the second modified portion r2 is greater than the size of the first modified portion r1, and by performing the second irradiation process between the first irradiation process and the second surface 12 side, the degradation of the electrical characteristics of the semiconductor layer 20 due to escaped light of the laser beam can be reduced while increasing the fracture strength of the sapphire substrate 10.

Spherical aberration may occur at the light concentration position of the laser beam inside the sapphire substrate 10 due to the refractive index difference between the air and the sapphire substrate 10. Spherical aberration is a phenomenon in which light rays of the laser beam diverge without converging at one point. Spherical aberration can be corrected by a spatial light modulator. For example, a spatial light modulator that includes a liquid crystal layer on which a prescribed modulation pattern is displayed can be used.

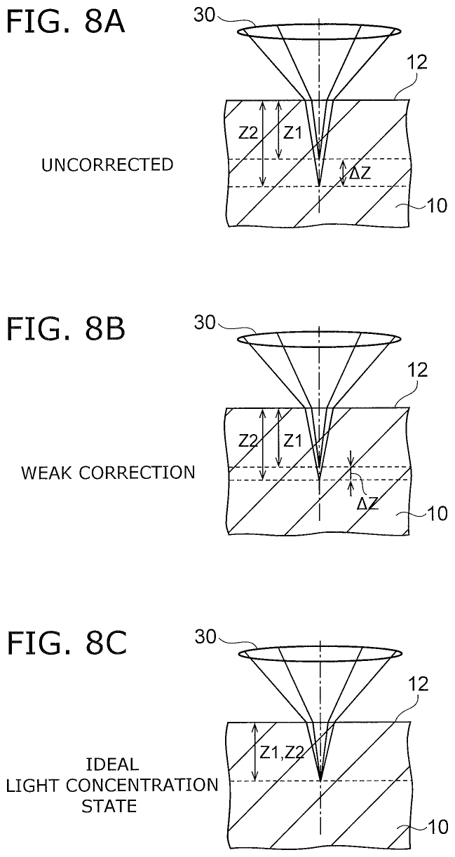

FIGS. 8A to 8C show light concentration states inside the sapphire substrate 10 when the laser beam is irradiated through air into the sapphire substrate 10 via a condensing lens 30. FIGS. 8A to 8C illustrate cross sections parallel to the thickness direction of the sapphire substrate 10.

FIG. 8A shows a light concentration state without aberration correction. FIG. 8B shows a weakly-corrected light concentration state in which the aberration correction amount is less than the ideal aberration correction amount. FIG. 8C shows the ideal light concentration state.

The ideal light concentration state is the state in which aberration correction is performed to cancel the spherical aberration occurring at the light concentration position of the laser beam, and is the light concentration state in which the aberration is reduced to approach the light concentration state assuming no medium (no sapphire substrate). The ideal aberration correction amount is the aberration correction amount that results in the ideal light concentration state in the medium. The weakly-corrected light concentration state is a state in which aberration correction is performed to cancel the spherical aberration to approach the ideal light concentration state. The aberration correction amount of the weakly-corrected light concentration state is less than the ideal aberration correction amount.

As shown in FIG. 8A, in the light concentration state when aberration correction is not performed, for example, a distance Z2 between the second surface 12 and the concentration point of the outer light rays of the laser beam is greater than a distance Z1 between the second surface 12 and the concentration point of the inner light rays of the laser beam; and a difference AZ occurs between Z1 and Z2. The distance Z1 and the distance Z2 are distances in the thickness direction of the sapphire substrate 10.

In the weakly-corrected light concentration state as shown in FIG. 8B, for example, the distance Z2 is greater than the distance Z1, and the difference AZ is less than when aberration correction is not performed.

In the ideal light concentration state as shown in FIG. 8C, the distance Z1 and the distance Z2 are equal, and the difference AZ does not occur.

The first modified portion r1 can be formed by setting the length in the thickness direction of the concentration region of the laser beam in the first irradiation process to be less than the length in the thickness direction of the concentration region of the laser beam without aberration correction.

In FIGS. 8A to 8C, the length in the thickness direction of the concentration region the laser beam is shortest in the ideal light concentration state shown in FIG. 8C. The escaped light from the concentration region of the laser beam can be reduced by using the ideal light concentration state. Accordingly, it is favorable to form the first modified portion r1 by performing aberration correction toward the ideal light concentration state so that the length in the thickness direction of the concentration region of the laser beam in the first irradiation process is less than the length in the thickness direction of the concentration region of the laser beam without aberration correction.

Or, the first modified portion r1 can be formed to have the weakly-corrected light concentration state shown in FIG. 8B so that the length in the thickness direction of the concentration region of the laser beam in the first irradiation process is less than the length in the thickness direction of the concentration region of the laser beam without aberration correction.

The second modified portion r2 can be formed so that the length in the thickness direction of the concentration region of the laser beam in the second irradiation process is greater than the length in the thickness direction of the concentration region of the laser beam without aberration correction.

For example, in the second irradiation process, the concentration point of the laser beam is formed at multiple positions arranged proximate to each other along the thickness direction of the sapphire substrate 10. Thereby, the second modified portion r2 can be formed so that the length in the thickness direction of the concentration region of the laser beam is greater than the length in the thickness direction of the concentration region of the laser beam without aberration correction. In such a case, for example, an axicon lens pattern can be displayed as the modulation pattern of the liquid crystal layer of the spatial light modulator. The laser beam is modulated by passing through the liquid crystal layer to form the concentration point of the laser beam at multiple positions arranged proximate to each other along the thickness direction of the sapphire substrate 10.

The length in the thickness direction z of the second concentration region of the laser beam forming the second modified portion r2 is set to be greater than the length in the thickness direction z of the first concentration region of the laser beam forming the first modified portion r1. As described above, there is a tendency for the size of the concentration region to increase as the length in the thickness direction z of the concentration region increases. Therefore, for the same laser beam output, the energy intensity of the laser beam per unit volume in the second concentration region can be less than the energy intensity of the laser beam per unit volume in the first concentration region.

It is therefore favorable to form the multiple first modified portions r1 by irradiating the laser beam at a first pulse energy in the first irradiation process and to form the multiple second modified portions r2 by irradiating the laser beam at a second pulse energy, which is greater than the first pulse energy, in the second irradiation process. Thereby, the pulse energy of the laser beam is unlikely to be insufficient when forming the second modified portion r2 in the second concentration region.

It is favorable for the first pulse energy of the laser beam for forming the first modified portion r1 to be, for example, not less than 0.6 μJ and not more than 1.8 μJ. It is favorable for the second pulse energy of the laser beam for forming the second modified portion r2 to be, for example, not less than 1.8 μJ and not more than 2.8 μJ. Thereby, sufficient laser beam pulse energy for forming the first modified portion r1 and the second modified portion r2 can be applied to the first and second concentration regions while suppressing effects on the semiconductor layer 20 of the laser beam in the first concentration region.

To reduce the degradation of the electrical characteristics of the semiconductor layer 20 due to the laser beam, it is favorable to form the first modified portion r1 in the first irradiation process by irradiating the laser beam at a position that is more proximate to the second surface 12 than the first surface 11 at which the semiconductor layer 20 is located.

In the first irradiation process shown in FIG. 3, the multiple first modified portions r1 can be formed by irradiating the laser beam at a first spacing P1 along the first direction a; and in the second irradiation process shown in FIG. 4, the multiple second modified portions r2 can be formed by irradiating the laser beam along the first direction a at a second spacing P2 that is greater than the first spacing P1.

When the second modified portion r2 is formed so that the length L2 in the thickness direction z of the second modified portion r2 is greater than the length L1 in the thickness direction z of the first modified portion r1, the length in the first direction a of the second modified portion r2 also easily becomes greater than the length in the first direction a of the first modified portion r1. In other words, the length in the first direction a of the second modified portion r2 can be set to be greater than the length in the first direction a of the first modified portion r1. Accordingly, the fracture strength can be increased because the size of the second modified portion r2 is increased.

In such a case, if the first spacing P1 of the multiple first modified portions r1 and the second spacing P2 of the multiple second modified portions r2 are equal, the multiple second modified portions r2 easily overlap each other in the first direction a because the second modified portion r2 is longer in the first direction a than the first modified portion r1. When the multiple second modified portions r2 are densely arranged in the first direction a, one second modified portion r2 exists proximate to another second modified portion r2 at which the stress is released by the generation of a crack, and so stress is not easily generated, and cracks do not easily extend. It is therefore favorable for the second spacing P2 of the multiple second modified portions r2 to be greater than the first spacing P1 of the multiple first modified portions r1.

The cracks from the second modified portions r2 extend toward the second surface 12 in the thickness direction z and extend in the scanning direction (in this case, the first direction a) of the laser beam. The cracks also can extend in a direction crossing the scanning direction (the first direction a) of the laser beam in a plane parallel to the second surface 12. When the multiple second modified portions r2 are densely arranged with each other in the scanning direction of the laser beam, meandering of the cracks occurs because the cracks that extend in directions other than the scanning direction (the first direction a) of the laser beam in the plane parallel to the second surface 12 inside the sapphire substrate 10 easily connect with each other. The meandering of cracks extending from the second modified portions r2 at the second surface 12 side cause chipping of the sapphire substrate 10 in the separation process described below. Also, when a reflective film is located at the second surface 12, the meandering of cracks at the second surface 12 side causes chipping of the reflective film. It is therefore favorable for the second spacing P2 of the multiple second modified portions r2 to be greater than the first spacing P1 of the multiple first modified portions r1 to reduce the meandering of cracks at the second surface 12 side.

To increase fracture strength while limiting the size of the second modified portion r2 and the pulse energy of the laser beam for forming the second modified portion r2 not to be greater than necessary, it is favorable for the length L2 in the thickness direction z of the second modified portion r2 to be not less than 1.3 times and not more than 3 times the length L1 in the thickness direction z of the first modified portion r1.

The first irradiation process and the second irradiation process described above can be performed for each of the multiple planned singulation lines L shown in FIG. 1. For example, after the first irradiation process and the second irradiation process are performed for the planned singulation lines L extending in the first direction a (the a-axis direction of the sapphire substrate 10), the first irradiation process and the second irradiation process can be performed for the planned singulation lines L extending in the second direction m (the m-axis direction of the sapphire substrate 10). Or, the first irradiation process and the second irradiation process can be performed for the planned singulation lines L extending in the first direction a after performing the first irradiation process and the second irradiation process for the planned singulation lines L extending in the second direction m. Also, the second irradiation process can be performed for the planned singulation lines L extending in the first direction a (the a-axis direction of the sapphire substrate 10) and the planned singulation lines L extending in the second direction m (the m-axis direction of the sapphire substrate 10) after performing the first irradiation process for the planned singulation lines L extending in the first direction a (the a-axis direction of the sapphire substrate 10) and the planned singulation lines L extending in the second direction m (the m-axis direction of the sapphire substrate 10).

The first irradiation process and the second irradiation process can be performed for the planned singulation lines L extending in the first direction a; and a third irradiation process and a fourth irradiation process described below can be performed for the planned singulation lines L extending in the second direction m.

### Third Irradiation Process

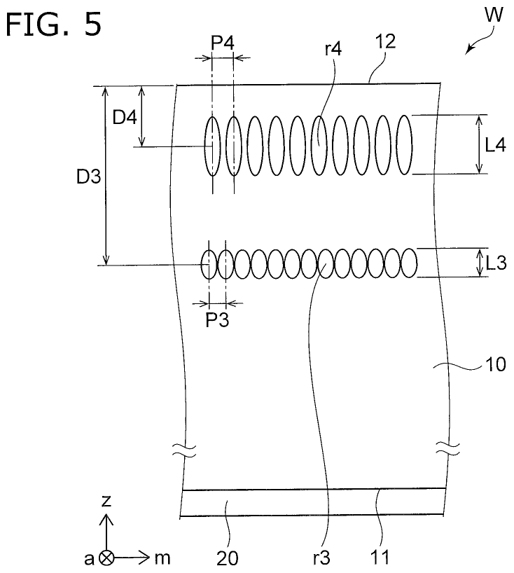

In the third irradiation process, the laser beam is irradiated along the second direction m. Thereby, as shown in FIG. 5, multiple third modified portions r3 are formed along the second direction m at a position that is a third distance D3 from the second surface 12 in the thickness direction z of the sapphire substrate 10. The third distance D3 is the distance from the second surface 12 to the center of the third modified portion r3 when viewed in cross-section.

For example, the multiple third modified portions r3 are formed to be separated from each other along the second direction m. Or, the multiple third modified portions r3 can be formed in a continuous line shape extending in the second direction m by causing portions of the third modified portion r3 next to each other in the second direction m to contact or overlap each other.

Cracks are generated from the multiple third modified portions r3 formed inside the sapphire substrate 10. Cracks that extend from the third modified portion r3 toward at least the second surface 12 are formed inside the sapphire substrate 10.

### Fourth Irradiation Process

The fourth irradiation process is performed after the multiple third modified portions r3 are formed by the third irradiation process.

In the fourth irradiation process as shown in FIG. 5, multiple fourth modified portions r4 are formed along the second direction m by irradiating the laser beam along the second direction m at a position that is a fourth distance D4 from the second surface 12 in the thickness direction z; and the fourth distance D4 is less than the third distance D3. The fourth distance D4 is the distance from the second surface 12 to the center of the fourth modified portion r4 when viewed in cross-section. The multiple fourth modified portions r4 are formed along the second direction m to be arranged in the thickness direction z with the multiple third modified portions r3. The multiple fourth modified portions r4 and the multiple third modified portions r3 are formed to overlap when viewed in top-view.

For example, the multiple fourth modified portions r4 are formed to be separated from each other along the second direction m. Or, the multiple fourth modified portions r4 can be formed in a continuous line shape extending in the second direction m by causing portions of the fourth modified portion r4 next to each other in the second direction m to contact or overlap each other.

Cracks that extend from the fourth modified portions r4 toward at least the second surface 12 are formed inside the sapphire substrate 10. It is favorable for the cracks from the fourth modified portions r4 to reach the second surface 12. Also, it is favorable for the cracks from the fourth modified portions r4 to reach the third modified portions r3.

The fourth modified portion r4 is formed in the fourth irradiation process so that a length L4 in the thickness direction z of the fourth modified portion r4 is greater than a length L3 in the thickness direction z of the third modified portion r3. The third modified portion r3 is formed so that the length L3 in the thickness direction z of the third modified portion r3 formed by concentrating the laser beam at a position that is more proximate to the semiconductor layer 20 than the fourth modified portion r4 is less than the length L4 in the thickness direction z of the fourth modified portion r4. In other words, the length in the thickness direction z of the third concentration region of the laser beam in the third irradiation process is set to be less than the length in the thickness direction z of the fourth concentration region of the laser beam in the fourth irradiation process. The escaped light from a third concentration region that is more proximate to the semiconductor layer 20 than a fourth concentration region can be reduced thereby, and the degradation of the electrical characteristics of the semiconductor layer 20 due to the laser beam can be reduced.

The fourth modified portion r4 is formed so that the length L4 in the thickness direction z of the fourth modified portion r4 in the fourth irradiation process of forming the fourth modified portion r4 at the position that is more distant to the semiconductor layer 20 than the third modified portion r3 is greater than the length L3 in the thickness direction z of the third modified portion r3. That is, the fourth irradiation process is performed so that the size of the fourth modified portion r4 is greater than the size of the third modified portion r3. The fracture strength of the sapphire substrate 10 can be increased thereby, and unintended cracking of the sapphire substrate 10 can be reduced. As a result, for example, chipping of the protective film covering the semiconductor layer 20 can be reduced. Because the fourth concentration region is more distant to the semiconductor layer 20 than the third concentration region, the escaped light from the fourth concentration region does not easily affect the semiconductor layer 20.

Similarly to the first irradiation process and the second irradiation process described above, in the third irradiation process and the fourth irradiation process as well, the spherical aberration at the light concentration position of the laser beam inside the sapphire substrate 10 can be corrected using a spatial light modulator.

Similarly to the first irradiation process, the third modified portion r3 can be formed so that the length in the thickness direction of the concentration region of the laser beam in the third irradiation process is less than the length in the thickness direction of the concentration region of the laser beam without aberration correction.

To further reduce the escaped light from the concentration region, it is favorable to form the third modified portion r3 by performing aberration correction toward the ideal light concentration state so that the length in the thickness direction of the concentration region of the laser beam in the third irradiation process is less than the length in the thickness direction of the concentration region of the laser beam without aberration correction.

Or, the third modified portion r3 can be formed by approaching the weakly-corrected light concentration state shown in FIG. 8B so that the length in the thickness direction of the concentration region of the laser beam in the third irradiation process is less than the length in the thickness direction of the concentration region of the laser beam without aberration correction.

Similarly to the second irradiation process, the fourth modified portion r4 can be formed so that the length in the thickness direction of the concentration region of the laser beam in the fourth irradiation process is greater than the length in the thickness direction of the concentration region of the laser beam without aberration correction.

It is favorable for the multiple third modified portions r3 to be formed in the third irradiation process by irradiating the laser beam at a third pulse energy, and for the multiple fourth modified portions r4 to be formed in the fourth irradiation process by irradiating the laser beam at a fourth pulse energy that is greater than the third pulse energy. Thereby, insufficient energy of the laser beam for forming the fourth modified portion r4 in the fourth concentration region does not easily occur.

It is favorable for the third pulse energy of the laser beam for forming the third modified portion r3 to be, for example, not less than 0.6 μJ and not more than 1.8 μJ. It is favorable for the fourth pulse energy of the laser beam for forming the fourth modified portion r4 to be, for example, not less than 1.8 μJ and not more than 2.8 μJ. Thereby, sufficient laser beam energy for forming the third modified portion r3 and the fourth modified portion r4 can be applied to the third and fourth concentration regions while suppressing effects on the semiconductor layer 20 of the laser beam in the third concentration region.

To reduce the degradation of the electrical characteristics of the semiconductor layer 20 due to the laser beam, it is favorable to form the third modified portion r3 in the third irradiation process by irradiating the laser beam at a position that is more proximate to the second surface 12 than the first surface 11 at which the semiconductor layer 20 is located.

The multiple third modified portions r3 can be formed in the third irradiation process by irradiating the laser beam at a third spacing P3 along the second direction m; and the multiple fourth modified portions r4 can be formed in the fourth irradiation process by irradiating the laser beam along the second direction m at a fourth spacing P4 that is greater than the third spacing P3.

When the fourth modified portion r4 is formed so that the length L4 in the thickness direction z of the fourth modified portion r4 becomes greater than the length L3 in the thickness direction z of the third modified portion r3, the length in the second direction m of the fourth modified portion r4 also easily becomes greater than the length in the second direction m of the third modified portion r3. In other words, the length in the second direction m of the fourth modified portion r4 can be set to be greater than the length in the second direction m of the third modified portion r3. Accordingly, the fracture strength can be increased because the size of the fourth modified portion r4 is increased.

In such a case, if the third spacing P3 of the multiple third modified portions r3 and the fourth spacing P4 of the multiple fourth modified portions r4 are equal, the fourth modified portion r4 has a longer length in the second direction m than the third modified portion r3; therefore, the multiple fourth modified portions r4 easily overlap each other in the second direction m. When the multiple fourth modified portions r4 are densely arranged with each other in the second direction m, one fourth modified portion r4 exists proximate to another fourth modified portion r4 at which the stress is released by the generation of a crack, and so stress is not easily generated, and cracks do not easily extend. It is therefore favorable for the fourth spacing P4 of the multiple fourth modified portions r4 to be greater than the third spacing P3 of the multiple third modified portions r3.

The cracks from the fourth modified portions r4 extend toward the second surface 12 in the thickness direction z and extend in the scanning direction (in this case, the second direction m) of the laser beam. The cracks also can extend in a direction crossing the scanning direction (the second direction m) of the laser beam in a plane parallel to the second surface 12. When the multiple fourth modified portions r4 are densely arranged with each other, meandering of the cracks occurs because the cracks that extend in directions other than the scanning direction (the second direction m) of the laser beam in the plane parallel to the second surface 12 easily connect with each other. The meandering of cracks extending from the fourth modified portions r4 at the second surface 12 side cause chipping of the sapphire substrate 10 in the separation process described below. Also, when a reflective film is located at the second surface 12, the meandering of cracks at the second surface 12 side causes chipping of the reflective film. It is therefore favorable for the fourth spacing P4 of the multiple fourth modified portions r4 to be greater than the third spacing P3 of the multiple third modified portions r3 to reduce the meandering of cracks at the second surface 12 side.

To increase fracture strength while limiting the size of the third modified portion r3 and the pulse energy of the laser beam for forming the fourth modified portion r4 not to be greater than necessary, it is favorable for the length L4 in the thickness direction z of the fourth modified portion r4 to be not less than 1.3 times and not more than 3 times the length L3 in the thickness direction z of the third modified portion r3.

In the sapphire substrate 10, cracks from the modified portion extend more easily along the a-axis direction (the first direction a) than the m-axis direction (the second direction m). Therefore, the multiple second modified portions r2 are formed by irradiating the laser beam in the second irradiation process at the second spacing P2 that is greater than the fourth spacing P4 so that the cracks from the second modified portions r2 arranged along the a-axis direction (the first direction a) easily connect in the a-axis direction (the first direction a) without meandering. Chipping of the sapphire substrate 10 and chipping of a reflective film when the film exists at the second surface 12 can be reduced thereby.

### Wafer W Separation Process

A separation process of the wafer W is performed after the laser beam irradiation process. For example, the sapphire substrate 10 is pressed with a pressing member from the first surface 11 side. The sapphire substrate 10 can be pressed with a pressing member from the second surface 12 side. The pressing member is, for example, a blade-shaped member that extends along the planned singulation line L. The sapphire substrate 10 receives the pressure of the pressing member from the first surface 11 side and cracks with the cracks extending from the modified portions r1 to r4 as starting points.

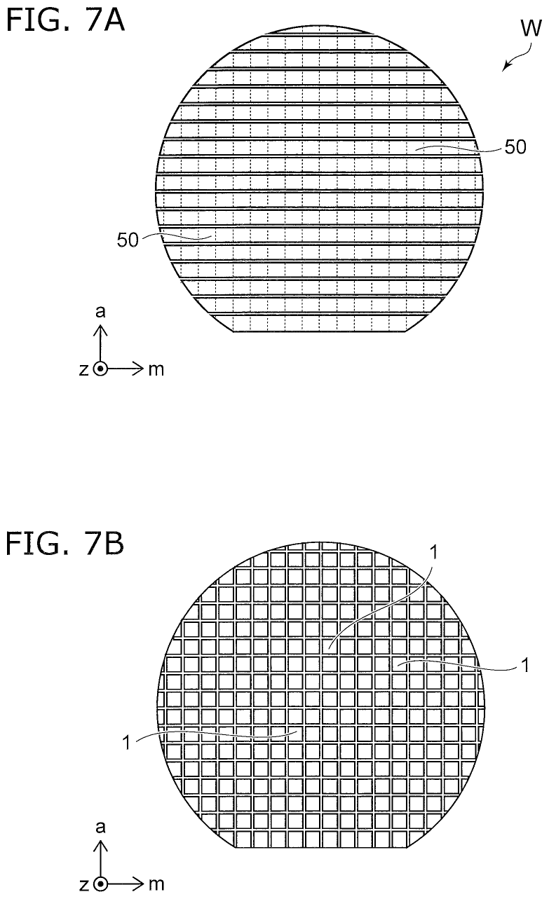

For example, first, the wafer W is cleaved along the planned singulation lines L extending along the second direction m; and the wafer W is separated into multiple base bodies 50 having shapes that extend in the second direction m as shown in FIG. 7A. Subsequently, the wafer W is separated into multiple light-emitting elements 1 as shown in FIG. 7B by cleaving the base bodies 50 along the planned singulation lines L extending along the first direction a. The cleaving along the first direction a can be performed first, followed by the cleaving along the second direction m.

The modified portions r1 to r4 described above are exposed at the side surfaces of the individual separated light-emitting elements 1.

FIG. 10 is a cross-sectional view of the light-emitting element 1 manufactured by the first embodiment. FIG. 10 shows a cross section of the sapphire substrate 10 parallel to the second direction m and the thickness direction z. A side surface 14 of the sapphire substrate 10 that is exposed by the cleaving along the first direction a extends in a direction extending through the page surface in FIG. 10.

The light-emitting element 1 includes the sapphire substrate 10, the semiconductor layer 20 located on the first surface 11 of the sapphire substrate 10, a first electrode 51, and a second electrode 52. The semiconductor layer 20 includes a first semiconductor layer 201, an active layer 202, and a second semiconductor layer 203 in this order from the first surface 11 side. For example, the first semiconductor layer 201 is of the n-type; and the second semiconductor layer 203 is of the p-type. The first electrode 51 is formed to be electrically connected to the first semiconductor layer 201; and the second electrode 52 is formed to be electrically connected to the second semiconductor layer 203. The light-emitting element 1 also can include a protective film 40 covering the semiconductor layer 20. The protective film 40 is an insulating film.

The side surface 14 of the sapphire substrate 10 includes a first region at which the first modified portions r1 are exposed and a second region at which the second modified portions r2 are exposed. For example, in the side surface 14 of the sapphire substrate 10, the regions at which the modified portions are exposed have greater surface roughness than portions at which modified portions are not formed. Also, the modified portions have lower light transmissivity than portions of the sapphire substrate 10 at which the modified portions are not formed. The first region at which the first modified portions r1 are exposed extends along the first direction a at a position that is separated from the first and second surfaces 11 and 12. The second region at which the second modified portions r2 are exposed extends along the first direction a at a position that is between the first region and the second surface 12 and separated from the second surface 12. The first region and the second region are more proximate to the second surface 12 than the first surface 11 in the thickness direction z of the sapphire substrate 10.

The portion of the side surface 14 of the sapphire substrate 10 at which the first region and the second region are not formed is a relatively flat region having low surface roughness; and the surface roughness of the first and second regions is greater than the surface roughness of the flat region. For example, the surface roughness of the side surface 14 of the sapphire substrate 10 can be measured by a laser microscope. For example, the Rz surface roughness is not less than 3 μm and not more than 7 μm for the first and second regions. For example, the Rz surface roughness is not less than 0.1 μm and not more than 2.5 μm for the flat region.

An implementation example of the method for manufacturing the light-emitting element according to the first embodiment will now be described.

### Example

The sapphire substrate 10 that was used had a thickness of 140 μm. First, in the first irradiation process, the multiple first modified portions r1 were formed by irradiating a laser beam at the first distance D1 of 58 μm from the second surface 12 inside the sapphire substrate 10 along the a-axis direction and the m-axis direction of the sapphire substrate 10. After the first irradiation process, the multiple second modified portions r2 were formed in the second irradiation process by irradiating a laser beam at the second distance D2 of 26 μm from the second surface 12 inside the sapphire substrate 10 along the a-axis direction and the m-axis direction of the sapphire substrate 10. In the first irradiation process, aberration correction of the laser beam was performed to realize the ideal light concentration state. In the second irradiation process, the length L2 in the thickness direction z of the second modified portion r2 was set to be greater than the length L1 in the thickness direction z of the first modified portion r1 by performing aberration correction of the laser beam to make the length in the thickness direction z of the second modified portion r2 greater than that of the uncorrected state. The first pulse energy of the laser beam for forming the first modified portion r1 was 1.2 μJ, and the second pulse energy of the laser beam for forming the second modified portion r2 was 2.5 μJ. The first spacing P1 of the multiple first modified portions r1 was 1.5 μm, and the second spacing P2 of the multiple second modified portions r2 was 3.5 μm. The fracture strength and the appearance failure rate were compared for the example and a reference example.

### Reference Example

For the reference example as well, the sapphire substrate 10 that had a thickness of 140 μm was used. In the first irradiation process of the reference example, the multiple first modified portions r1 were formed by irradiating the laser beam at the first distance D1 of 58 μm from the second surface 12 inside the sapphire substrate 10 along the a-axis direction and the m-axis direction of the sapphire substrate 10. After the first irradiation process, the multiple second modified portions r2 were formed in the second irradiation process by irradiating the laser beam at the second distance D2 of 26 μm from the second surface 12 inside the sapphire substrate 10 along the a-axis direction and the m-axis direction of the sapphire substrate 10. In the reference example, the length L1 in the thickness direction z of the first modified portion r1 and the length L2 in the thickness direction z of the second modified portion r2 were set to be equal by performing aberration correction to realize the ideal light concentration state in the first and second irradiation processes. In the reference example, the first pulse energy of the laser beam for forming the first modified portion r1 and the second pulse energy of the laser beam for forming the second modified portion r2 were equal, i.e., 1.4 μJ each. Also, in the reference example, the first spacing P1 of the multiple first modified portions r1 and the second spacing P2 of the multiple second modified portions r2 were equal, i.e., 3.0 μm.

The fracture strength (N) after the laser beam irradiation process of the example described above was about 1.6 times the fracture strength (N) after the laser beam irradiation process of the reference example described above. The appearance failure rate after the laser beam irradiation process of the example described above was about ⅛ of the appearance failure rate after the laser beam irradiation process of the reference example described above. The occurrence of chipping of the protective film at the first surface 11 side of the sapphire substrate 10 was included in the appearance failures.

### Second Embodiment

A laser beam irradiation process of a second embodiment will now be described.

The laser beam irradiation process of the second embodiment further includes a fifth irradiation process performed after the first irradiation process and before the second irradiation process. The fifth irradiation process can be performed after the third irradiation process and before the fourth irradiation process.

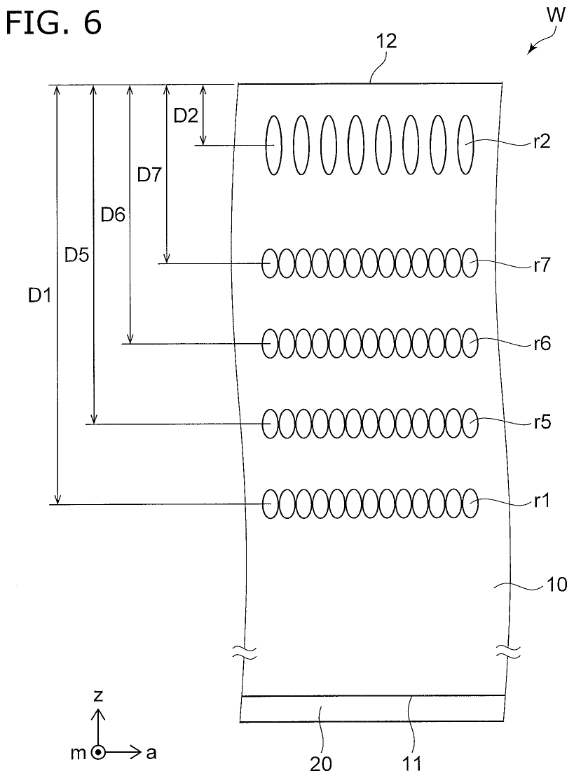

In the following description, an example is described with reference to FIG. 6 in which the fifth irradiation process is performed after the first irradiation process and before the second irradiation process. The first irradiation process and the second irradiation process are performed similarly to the first embodiment. According to the second embodiment, the first modified portions r1 are formed by performing aberration correction to realize the ideal light concentration state so that the length in the thickness direction of the concentration region of the laser beam in the first irradiation process is set to be less than the length in the thickness direction of the concentration region of the laser beam without aberration correction. Also, according to the second embodiment, the second modified portions r2 are formed by realizing the weakly-corrected light concentration state shown in FIG. 8B so that the length in the thickness direction in the second irradiation process is greater than that of the first modified portions r1. By realizing the weakly-corrected light concentration state in the second irradiation process, the fracture strength can be increased while reducing the meandering of cracks at the second surface 12 side.

After forming the multiple first modified portions r1 by the first irradiation process, the multiple fifth modified portions that are arranged in the thickness direction z with the multiple first modified portions r1 are formed along the first direction a by irradiating the laser beam along the first direction a so that the distance from the second surface 12 in the thickness direction z in the position of the fifth irradiation process is less than the first distance D1 and greater than the second distance D2.

The fifth modified portion that is formed at the position having the distance from the second surface 12 that is less than the first distance D1 and greater than the second distance D2 includes at least one of modified portions r5, r6, and r7 that are formed at mutually-different distances from the second surface 12.

In the example shown in FIG. 6, after forming the multiple first modified portions r1, the multiple modified portions r5 are formed along the first direction a by irradiating the laser beam along the first direction a so that the distance from the second surface 12 in the thickness direction z is a fifth distance D5 that is less than the first distance D1. The fifth distance D5 is the distance from the second surface 12 to the center of the modified portion r5 when viewed in cross-section. The multiple modified portions r5 are formed along the first direction a to be arranged in the thickness direction z with the multiple first modified portions r1. The multiple fifth modified portions r5 and the multiple first modified portions r1 are formed to overlap when viewed in top-view.

After forming the multiple modified portions r5, the multiple modified portions r6 are formed along the first direction a by irradiating the laser beam along the first direction a so that the distance from the second surface 12 in the thickness direction z is a sixth distance D6 that is less than the fifth distance D5. The sixth distance D6 is the distance from the second surface 12 to the center of the modified portion r6 when viewed in cross-section. The multiple modified portions r6 are formed along the first direction a to be arranged in the thickness direction z with the multiple first modified portions r1 and the multiple modified portions r5.

After forming the multiple modified portions r6, the multiple modified portions r7 are formed along the first direction a by irradiating the laser beam along the first direction a at a seventh distance D7, which is less than the sixth distance D6, from the second surface 12 in the thickness direction z. The seventh distance D7 is the distance from the second surface 12 to the center of the modified portion r7 when viewed in cross-section. The multiple modified portions r7 are formed along the first direction a to be arranged in the thickness direction z with the multiple first modified portions r1, the multiple modified portions r5, and the multiple modified portions r6.

After forming the multiple modified portions r7, the multiple second modified portions r2 are formed along the first direction a by irradiating the laser beam along the first direction a at the second distance D2, which is less than the seventh distance D7, from the second surface 12 in the thickness direction z.

In the second irradiation process of the second embodiment, the second modified portion r2 is formed so that the length in the thickness direction z of the second modified portion r2 is greater than the lengths in the thickness direction z of the modified portions r5 to r7.

According to the second embodiment, the following effects are obtained in addition to the effects of the first embodiment described above.

The multiple fifth modified portions that are arranged in the thickness direction z with the multiple first modified portions r1 are formed along the first direction a so that the distance from the second surface 12 in the thickness direction z of the sapphire substrate 10 is less than the first distance D1 and greater than the second distance D2; therefore, the cracks that are generated from the modified portions easily connect in the thickness direction z; and the sapphire substrate 10 can be easily cleaved even when the sapphire substrate 10 is thick. Here, a thick sapphire substrate 10 means that, for example, the thickness of the sapphire substrate 10 is not less than 400 μm. Also, according to the second embodiment, the pulse energy of the laser beam in the laser beam irradiation processes can be, for example, not less than 3 μJ and not more than 9 μJ.

According to the second embodiment, one modified portion is formed by multiple laser beam irradiations at the same position inside the sapphire substrate 10. For example, the multiple first modified portions r1 are formed by twice repeating the scanning along the first direction a of the irradiation of the laser beam at the positions at which the first modified portions r1 are formed. After forming the first modified portions r1, the multiple modified portions r5 are formed by twice repeating the scanning along the first direction a of the irradiation of the laser beam at the positions at which the modified portions r5 are formed. After forming the modified portions r5, the multiple modified portions r6 are formed by twice repeating the scanning along the first direction a of the irradiation of the laser beam at the positions at which the modified portions r6 are formed. After forming the modified portions r6, the multiple modified portions r7 are formed by twice repeating the scanning along the first direction a of the irradiation of the laser beam at the positions at which the modified portions r7 are formed. After forming the modified portions r7, the multiple second modified portions r2 are formed by twice repeating the scanning along the first direction a of the irradiation of the laser beam at the positions at which the second modified portions r2 are formed.

By using two laser beam irradiations to form one modified portion, the second laser beam irradiation can easily cause the cracks of the first laser beam irradiation to extend with less meandering in the thickness direction z.

In the laser beam irradiations that form the first modified portion r1 and the fifth modified portions r5 to r7, the pulse energy of the laser beam and the irradiation spacing in the first direction a are respectively the same between the first and second irradiations.

In the laser beam irradiation that forms the second modified portion r2, the pulse energy of the laser beam is the same between the first and second irradiations, and the pulse energy of the laser beam of the second irradiation is greater than the pulse energy of the laser beam of the first irradiation. In the laser beam irradiation that forms the second modified portion r2, the irradiation spacing in the first direction a of the first irradiation is greater than the irradiation spacing in the first direction a of the second irradiation. Thus, the cracks that are formed by the first laser beam irradiation can be caused to extend more efficiently by irradiating the laser beam in the second laser beam irradiation.

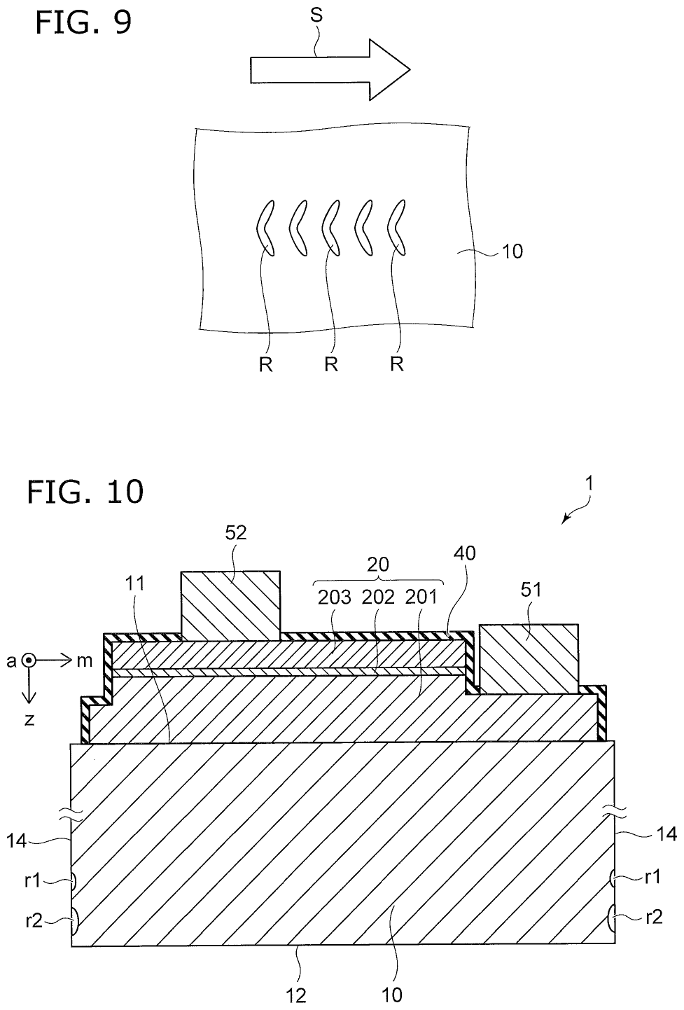

FIG. 9 is a cross-sectional view showing an example of the shape of a concentration region R inside the sapphire substrate of the laser beam for forming the modified portions according to the embodiments described above. In FIG. 9, the vertical direction is the thickness direction of the sapphire substrate 10; and the shape of the concentration region R shown in FIG. 9 is the shape when viewed in cross-section parallel to the thickness direction of the sapphire substrate 10. Also, the arrow S shown in FIG. 9 illustrates the scanning direction of the laser beam.

For example, the shape of the concentration region R can be adjusted by adjusting the modulation pattern displayed in the liquid crystal layer of the spatial light modulator. In the example shown in FIG. 9, the shape of the concentration region R is adjusted to be an arc shape that is convex toward the opposite direction of the scanning direction S of the laser beam. By adjusting the shape of the concentration region R to be an arc shape that is convex toward the opposite direction of the scanning direction S of the laser beam, it is easier for the cracks to extend from the modified portions than when the shapes of the multiple concentration regions are symmetric in the scanning direction S and the opposite direction. The shape of the concentration region R can be an arc shape that is convex toward the opposite direction of the scanning direction S of the laser beam in the first to fifth irradiation processes. By setting the shape of the concentration region R to be an arc shape that is convex toward the opposite direction of the scanning direction S of the laser beam, the cracks can extend more easily from the modified portions. When the shape of the concentration region R is set to be an arc shape that is convex toward the opposite direction of the scanning direction S of the laser beam, it is favorable for the irradiation spacing of the laser beam to be not less than 1 μm and not more than 4 μm so that the cracks can extend more easily from the modified portions. It is favorable for the irradiation spacing of the laser beam to be not less than 1 μm and not more than 2.5 μm in the first, third, and fifth irradiation processes. It is favorable for the irradiation spacing of the laser beam to be not less than 2 μm and not more than 4 μm in the second and fourth irradiation processes.

Hereinabove, exemplary embodiments of the invention are described with reference to specific examples. However, the invention is not limited to these specific examples. All configurations practicable by an appropriate design modification by one skilled in the art based on the embodiments of the invention described above also are within the scope of the invention to the extent that the purport of the invention is included. Furthermore, various modifications and alterations within the spirit of the invention will be readily apparent to those skilled in the art. All such modifications and alterations should therefore be seen as within the scope of the invention.

What is claimed is:

1. A method for manufacturing a light-emitting element, the method comprising:
preparing a wafer, the wafer including
a sapphire substrate including a first surface on a first surface side and a second surface on a second surface side opposite to the first surface side, and
a semiconductor layer located at the first surface;
a laser beam irradiation process of irradiating a laser beam into the sapphire substrate from the second surface side; and
a separation process of separating the wafer into a plurality of light-emitting elements after the laser beam irradiation process, wherein
the laser beam irradiation process includes:
a first irradiation process of forming a plurality of first modified portions along a first direction parallel to the second surface by irradiating the laser beam along the first direction, the plurality of first modified portions being formed at positions that are a first distance from the second surface in a thickness direction of the sapphire substrate; and
a second irradiation process of forming a plurality of second modified portions along the first direction by irradiating the laser beam along the first direction, the plurality of second modified portions being formed at positions that are a second distance from the second surface in the thickness direction, the second distance being less than the first distance, the plurality of second modified portions being arranged in the thickness direction with the plurality of first modified portions, and
the second modified portions are formed in the second irradiation process so that a length in the thickness direction of the second modified portions is greater than a length in the thickness direction of the first modified portions.

2. The method according to claim 1, wherein
the second modified portions are formed so that a length in the thickness direction of a concentration region of the laser beam in the second irradiation process is greater than a length in the thickness direction of a concentration region of the laser beam without aberration correction.

3. The method according to claim 1, wherein
the first modified portions are formed so that a length in the thickness direction of a concentration region of the laser beam in the first irradiation process is less than a length in the thickness direction of a concentration region of the laser beam without aberration correction.

4. The method according to claim 1, wherein
the plurality of first modified portions is formed in the first irradiation process by irradiating the laser beam at a first pulse energy,
the plurality of second modified portions is formed in the second irradiation process by irradiating the laser beam at a second pulse energy, and
the second pulse energy is greater than the first pulse energy.

5. The method according to claim 1, wherein
the plurality of first modified portions is formed in the first irradiation process by irradiating the laser beam at a first spacing,
the plurality of second modified portions is formed in the second irradiation process by irradiating the laser beam at a second spacing, and
the second spacing is greater than the first spacing.

6. The method according to claim 1, wherein
the first direction is along an a-axis direction of the sapphire substrate,
the laser beam irradiation process further includes:
a third irradiation process of forming a plurality of third modified portions along a second direction by irradiating the laser beam along the second direction, the second direction being along an m-axis direction of the sapphire substrate, the plurality of third modified portions being formed at positions that are a third distance from the second surface in the thickness direction; and
a fourth irradiation process of forming a plurality of fourth modified portions along the second direction by irradiating the laser beam along the second direction, the plurality of fourth modified portions being formed at positions that are a fourth distance from the second surface in the thickness direction, the fourth distance being less than the third distance, the plurality of fourth modified portions being arranged in the thickness direction with the plurality of third modified portions, and
the fourth modified portions are formed so that a length in the thickness direction of the fourth modified portions in the fourth irradiation process is greater than a length in the thickness direction of the third modified portions.

7. The method according to claim 5, wherein
the first direction is along an a-axis direction of the sapphire substrate,
the laser beam irradiation process further includes:
a third irradiation process of forming a plurality of third modified portions along a second direction by irradiating the laser beam along the second direction, the second direction being along an m-axis direction of the sapphire substrate, the plurality of third modified portions being formed at positions that are a third distance from the second surface in the thickness direction; and
a fourth irradiation process of forming a plurality of fourth modified portions along the second direction by irradiating the laser beam along the second direction, the plurality of fourth modified portions being formed at positions that are a fourth distance from the second surface in the thickness direction, the fourth distance being less than the third distance, the plurality of fourth modified portions being arranged in the thickness direction with the plurality of third modified portions, and
the fourth modified portions are formed so that a length in the thickness direction of the fourth modified portions in the fourth irradiation process is greater than a length in the thickness direction of the third modified portions.

8. The method according to claim 6, wherein
the plurality of third modified portions is formed in the third irradiation process by irradiating the laser beam at a third spacing,
the plurality of fourth modified portions is formed in the fourth irradiation process by irradiating the laser beam at a fourth spacing, and
the fourth spacing is greater than the third spacing.

9. The method according to claim 7, wherein
the plurality of third modified portions is formed in the third irradiation process by irradiating the laser beam at a third spacing,
the plurality of fourth modified portions is formed in the fourth irradiation process by irradiating the laser beam at a fourth spacing, and
the fourth spacing is greater than the third spacing.

10. The method according to claim 8, wherein
the plurality of second modified portions is formed in the second irradiation process by irradiating the laser beam at a second spacing, and
the second spacing is greater than the fourth spacing.

11. The method according to claim 9, wherein
the second spacing is greater than the fourth spacing.

12. The method according to claim 6, wherein
the laser beam is irradiated at a position more proximate to the second surface than the first surface in the third irradiation process.

13. The method according to claim 1, wherein
the laser beam is irradiated at a position more proximate to the second surface than the first surface in the first irradiation process.

14. The method according to claim 1, wherein
the laser beam irradiation process further includes a fifth irradiation process performed after the first irradiation process and before the second irradiation process,
the fifth irradiation process includes forming a plurality of fifth modified portions along the first direction by irradiating the laser beam along the first direction, the plurality of fifth modified portions being formed at a distance from the second surface in the thickness direction that is less than the first distance and greater than the second distance, the plurality of fifth modified portions being arranged in the thickness direction with the plurality of first modified portions, and
the second modified portions are formed in the second irradiation process so that the length in the thickness direction of the second modified portions is greater than a length in the thickness direction of the fifth modified portions.

15. The method according to claim 1, wherein
the length in the thickness direction of the second modified portions is not less than 1.3 times and not more than 3 times the length in the thickness direction of the first modified portions.

16. The method according to claim 1, wherein
the length in the first direction of the second modified portions is greater than the length in the first direction of the first modified portions.
